(19) United States
(12) Patent Application Publication
(10) Pub. No.: US 2004/0224446 A1
(43) Pub. Date: Nov. 11, 2004

(54) [STRUCTURE OF THIN-FILM TRANSISTOR AND METHOD AND EQUIPMENT FOR FABRICATING THE STRUCTURE]

(76) Inventor: Wen-Chang Yeh, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/709,412

(22) Filed: May 4, 2004

(30) Foreign Application Priority Data
May 7, 2003 (JP) 2003-164366

(51) Int. Cl. H01L 21/00; H01L 21/84

(52) U.S. Cl. 438/166; 438/308

(57) ABSTRACT

The invention is directed to method for fabricating a TFT. A semiconductor film is formed over a substrate. A semiconductor island is formed by patterning the semiconductor film. An insulating film is formed over the substrate. An optical annealing process is performed to crystallize the semiconductor island. A transistor is formed on the semiconductor island. Also, a patterning method on an amorphous semiconductor film uses a light beam to illuminate through a mask onto the amorphous semiconductor film, so as to crystallize a portion of the amorphous semiconductor film into a crystal semiconductor portion, or form an oxide on the amorphous semiconductor island in an oxygen ambience. Then, a gas etching process, such as H atoms, is performed to remove a portion of the amorphous semiconductor not being illuminated by the laser.

### CROSS REFERENCE TO RELATED APPLICATIONS

This application claims the priority benefit of Japanese application serial No. 2003-164366, filed May 07, 2003.

### BACKGROUND OF INVENTION

1. Field of Invention

The present invention relates to thin-film transistor (TFT). More particularly, the present invention relates to technology for fabricating a crystalline Si TFT using excimer laser.

2. Description of Related Art

In the following descriptions, the semiconductor material, such as silicon or germanium, are used. However, silicon is used as the example for descriptions.

In recent years, it is strongly intended for the developments of TFT, used to drive the pixel in Active Matrix Liquid Crystal Display (AMLCD) or the Active Matrix Organic Light Emission Display (AMOLED). The TFT can be a polysilicon TFT or an amorphous-silicon (a-Si) TFT.

For the polysilicon TFT, since it has high mobility, it is promising for use in driving the pixels, and use as a part of peripheral driving circuit, or even use in circuit fabrication by forming the process circuit directly on a glass or plastic substrate.

If the TFT is used to achieve a sufficiently-high information processing speed, it is necessary to increase the mobility up to 300 cm²/V-s. In order to achieve such high mobility, the quality for the crystal silicon film and the gate insulator should be sufficiently good. However, with respect to the silicon film, the current technology can only form polysilicon film on a glass substrate. The gain boundary of polysilicon actives as an electron scattering center, therefore, the grain boundary reduces the mobility of TFT. On the other hand, with respect to the gate insulator, since the fabrication temperature is restricted to be less than 500° C., the oxide charges of the gate insulator and the interface states are usually high. In addition, for the current fabrication processes for TFT, before deposition of the gate insulator, the photolithography and etching processes for forming the active semiconductor islands of transistor are performed. This photolithographic process causes the poor quality between the semiconductor film and the gate insulator. The quality between the semiconductor film and the gate insulator not only reduces the threshold voltage of the TFT but also raises the subthreshold (S) swing, also and the mobility is reduced. In order to obtain high performance TFT, it is that not only the grain boundary in the channel is necessary to be reduced, but also it is necessary to form the gate insulator in high quality, and have high interface quality between the semiconductor film and the gate insulator.

With respect to improving quality of the polysilicon film, in recent years, the silicon film can have lateral growth induced by excimer laser, so that the direction of lateral growth can along the channel direction of TFT. As a result, when the carriers move over the channel, the carriers are not necessary to cross the grain boundaries, resulting in a high mobility by greater than 400 cm²/V-s. Therefore, the technology for fabricating the TFT with the lateral growth is recently developed one after one. In general, the lateral growth can be achieved by creating a temperature grading on surface of a melted silicon film, whereby the crystal growth can occur from the low temperature to high temperature. The method for having the temperature grading on the silicon film can use laser to have an intensity distribution in space. Since the silicon film absorbs different laser intensity in different locations, the temperature grading on the silicon film is created. The method for giving distribution of laser intensity in space is, for example, the Super Lateral Solidified (SLS) Excimer Laser Annealing, or the phase modulated Excimer Laser Annealing (PMELA) method. However, these methods need the light beam to be modulated by either light mask or phase shift mask, and these cause the increase of the optical system of laser annealing facility and also cause the increase of the fabrication cost of TFTs. The manufacturers have produced the first generation of low-temperature TFT in mass production, wherein the crystallization of silicon film is performed by excimer laser annealing system. However, this kind of first generation for the excimer laser annealing system can only uniformly illuminate the silicon film. In this manner, the grains are formed randomly, and the lateral growth cannot be obtained. If the first generation of the excimer laser annealing system with the uniform laser intensity can be used to have lateral growth, then it is not necessary to have extra cost for the new generation of the excimer laser annealing system. The fabrication cost can be reduced.

For the gate insulator, since the fabrication temperature for TFT is restricted to be less than 500° C. due to the thermal endurance of glass substrate, the current method cannot form the gate insulating film in sufficient quality. The current deposition method for the insulating film is plasma enhanced chemical vapor deposition (PECVD). However, since the plasma is used, it may cause charge damage on the insulating film. In order to reduce the damage on the insulating film, the ECR-plasma enhanced chemical vapor deposition (ECR-PECVD) is developed. The high-pressure water vapor or high-pressure oxygen annealing method is also developed later. However, the ECR-PECVD machine is still involved and the fabrication process is complicate. The laser annealing method of silicon nitride film for gate insulator have ever been invented, however, the absorption coefficient of the silicon nitride film is over high and results in that the light beam is instantly absorbed at the surface of the silicon nitride film with difficulty to enter the deep part of the silicon nitride film. As a result, the annealing effect is insufficient.

For another well-known fabrication process in top-gate TFT, the silicon film serving as semiconductor film is first patterned by photolithographic and etching processes to form the active silicon islands of TFT. Then, the silicon oxide serving as the gate insulator of the TFT is deposited on the silicon islands. However, in this patterning process, the silicon film is exposed to the air during transportation, and further the silicon film is coated by the photoresist, the surface of silicon film is easily to be contaminated or adhered with dust particles. This causes the difficult to maintain a clean interface between the semiconductor film and the gate insulator, and resulting in reducing the TFT performance and causing low yield of TFT. In order to solve the above problems, it is necessary to develop the photolithography and etching technology without using the photoresist and the TFT fabrication processes without exposed to the air from forming the active semiconductor film, patterning the semiconductor film to form the semiconductor island, and to depositing of the gate insulator.

### SUMMARY OF INVENTION

The invention provides a method for fabricating the TFT with improved performance, wherein the foregoing conventional issues can be effectively solved.

It is not necessary to include the photoresist used in conventional photolithographic and etching processes. Also and, the photolithographic and etching processes are not necessary to be exposing under the air. By a simple process, the silicon island by lateral growth or single-crystal silicon island can be achieved. The property of gate insulator can be improved. As a result, the fabrication process for TFT can significantly improve the TFT performance, the yield, and the throughput.

The invention provides a method for fabricating a TFT. A semiconductor film is formed over a substrate. A semiconductor island is formed by patterning the semiconductor film. An insulating film is formed over the substrate.

An optical annealing, such as laser annealing, process is performed to crystallize the semiconductor island. A transistor is formed on the semiconductor island.

In another aspect, a patterning method on an amorphous semiconductor film uses a light beam, such as laser beam, to illuminate through a mask onto the amorphous semiconductor film, so as to crystallize a portion of the amorphous semiconductor film into a crystal semiconductor portion, or form an oxide on the amorphous semiconductor island in an oxygen ambience. Then, a gas etching process, such as H atoms, is performed to remove a portion of the amorphous semiconductor not being illuminated by the laser.

In another aspect, a structure of thin-film transistor (TFT) comprises a poly-crystal semiconductor island, formed on a substrate. Wherein, the poly-crystal semiconductor island is with respect to a rectangular region having a long side and a short side. A plurality long-shape crystal grains from a center strip region along the direction of the long side to the long side. A gate insulating film is disposed over the semiconductor island. A strip gate is located on the gate insulating film between the center grain boundary and the long side, wherein a direction of the strip gate in along the direction of the long side. A source region and a drain region are parts of the semiconductor island at each side of the strip gate.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1 Fare cross-sectional views, schematically illustrating the process flow diagram for fabricating TFT over a substrate, according to a preferred embodiment of the invention.

FIG. 2 is a drawing, schematically illustrating the lateral growth length with respect to thickness of the semi-transparent layer.

FIG. 3 is a drawing, schematically illustrating the etching rate with respect to hydrogen atoms in amorphous silicon, polysilicon silicon, and silicon oxide.

FIGS. 4A-4B are drawings, schematically illustrating the novel etching process of surface-oxide, according to a preferred embodiment of the invention.

FIGS. 5A-5B are drawings, schematically illustrating the novel etching process of phase-change, according to a preferred embodiment of the invention.

FIG. 6 is a drawing, schematically illustrating the equipment of semiconductor fabrication in multiple chambers, according to a preferred embodiment of the invention.

FIGS. 7A-7F are cross-sectional views, schematically illustrating the TFT, according to a preferred embodiment of the invention.

FIGS. 8A-8F are cross-sectional views, schematically illustrating the TFT, according to another preferred embodiment of the invention.

FIGS. 9A-9F are cross-sectional views, schematically illustrating the TFT, according to another preferred embodiment of the invention.

FIGS. 10A-10D are cross-sectional views, schematically illustrating the shape of semiconductor island in the process FIG. 1B, according to another preferred embodiment of the invention.

FIGS. 11A-11F are cross-sectional views, schematically illustrating in the process FIG. 1D, according to another preferred embodiment of the invention.

### DETAILED DESCRIPTION

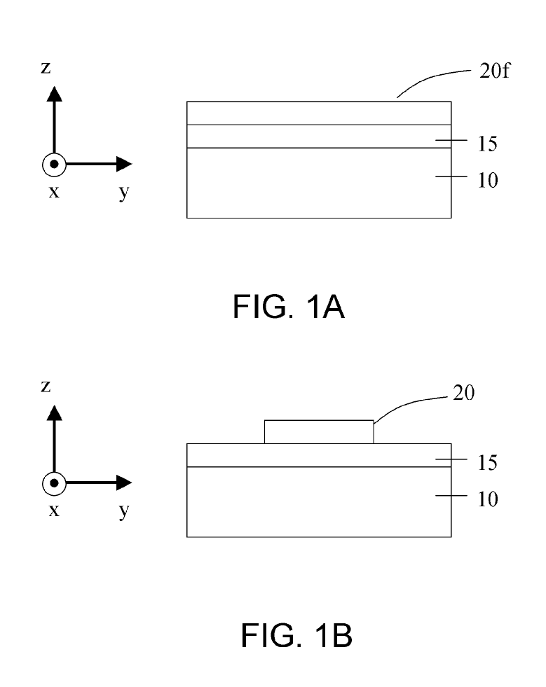

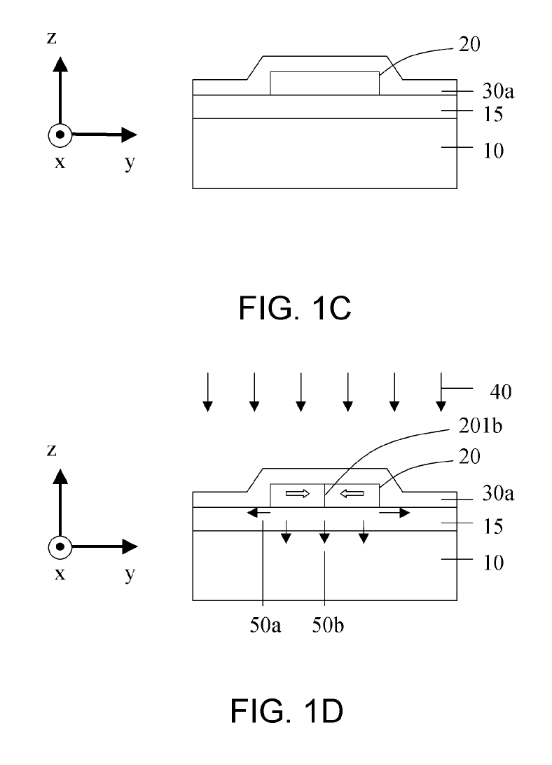

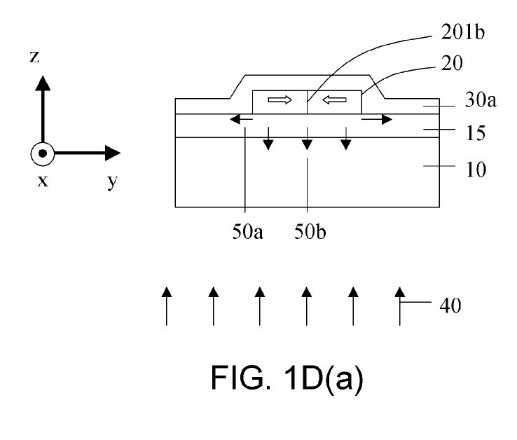

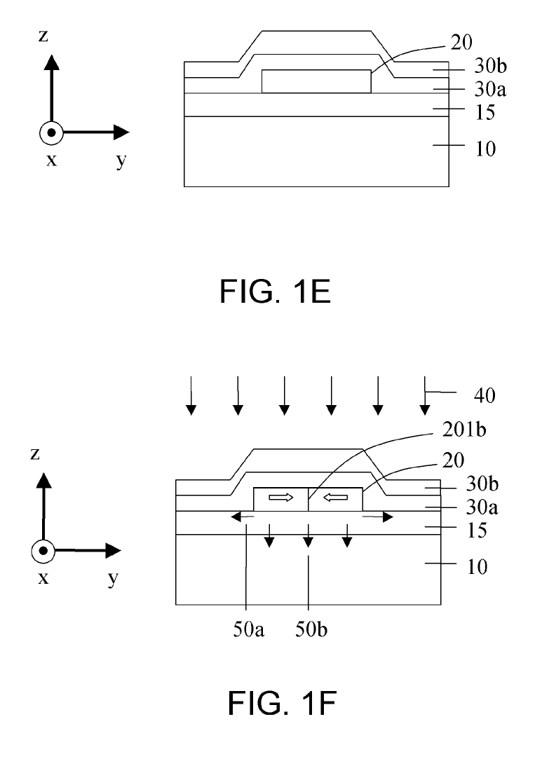

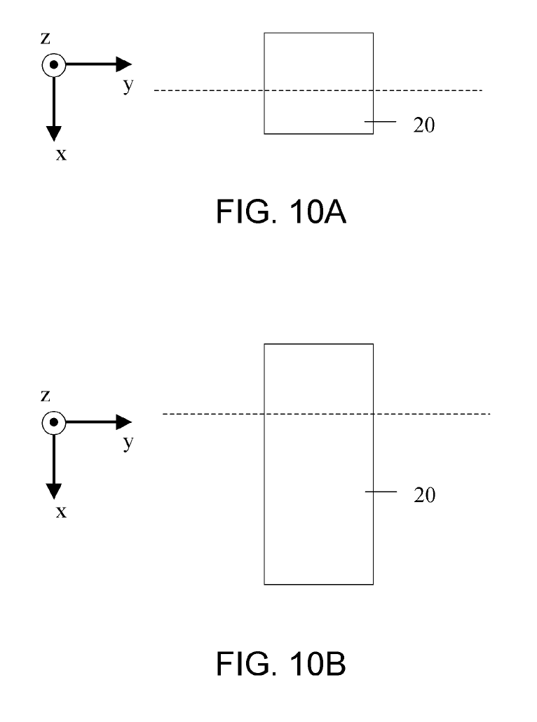

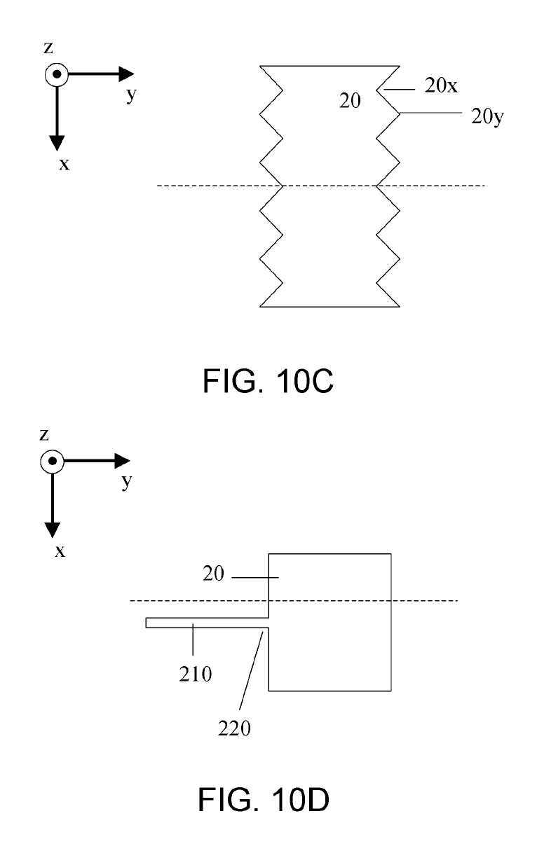

In the invention, the crystallization of the semiconductor film is described first. FIGS. 1A-1 Fare cross-sectional views, schematically illustrating the process flow diagram for fabricating TFT over a substrate, according to a preferred embodiment of the invention. The coordinate system of xyz is shown at left side, in which the substrate is parallel to the xy plane. In FIG. 1A, a protection film 15, from silicon oxide as an example, is formed over the substrate 10. A semiconductor film 20f is then deposited over the protection film 15. In FIG. 1B, the semiconductor film 20f is patterned by, for example, photolithographic and etching processes to form a TFT active region as a semiconductor island 20. The surface of the semiconductor island 20 has the shape as shown in FIGS. 10A-10D to be described later. The semiconductor-island formation process can refer to steps in FIG. 1A to FIG. 1B to form the semiconductor island 20. In FIG. 1C, an insulating film 30a is formed over the semiconductor island 20 and the protection film 15, as referred to be the covering film formation process. In FIG. 1D, a light beam, such as a light beam, 40 illuminates over the substrate 10 from the front side. However, the light beam 40 can also illuminate from the bottom side of the substrate 10, as for example shown in FIG. 1D(a), in which the mechanism and the crystallization process remain the same effects. In the crystallization process, after the semiconductor film 20 is melt, the periphery of the semiconductor island 20 has the lateral thermal flow 50a and a downward thermal flow 50b. The center region of the semiconductor island 20 can only have the downward thermal flow 50b, therefore, the temperature at the side peripheral region decreases in relative faster speed. The occurrence of crystallization seeds at the side peripheral region of the semiconductor island 20 is earlier, wherein the lateral growth occurs from the side of the semiconductor island 20 to the center region.

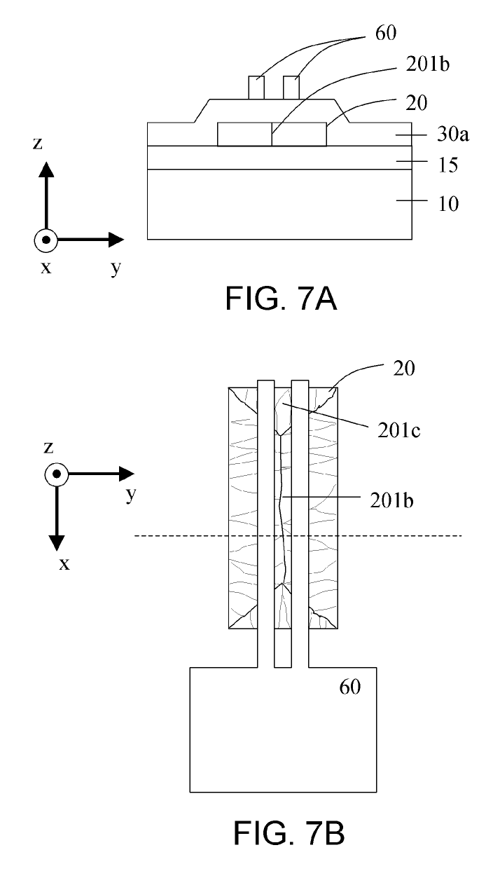

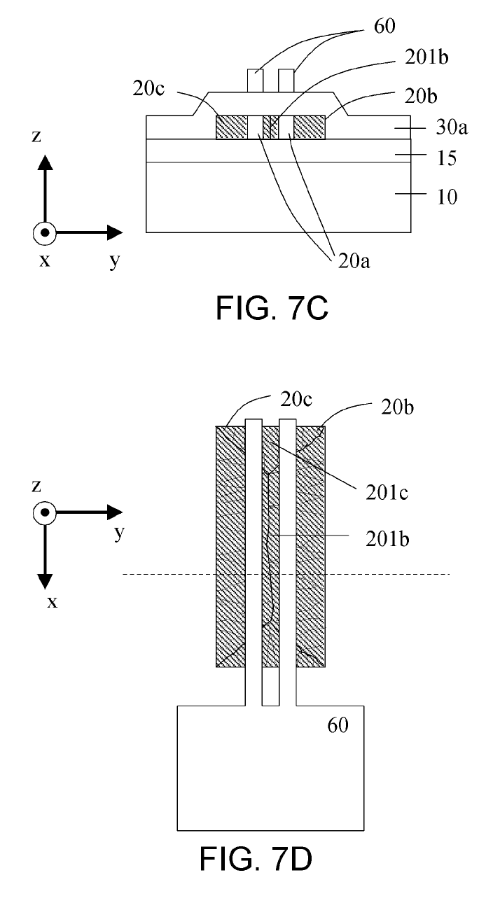

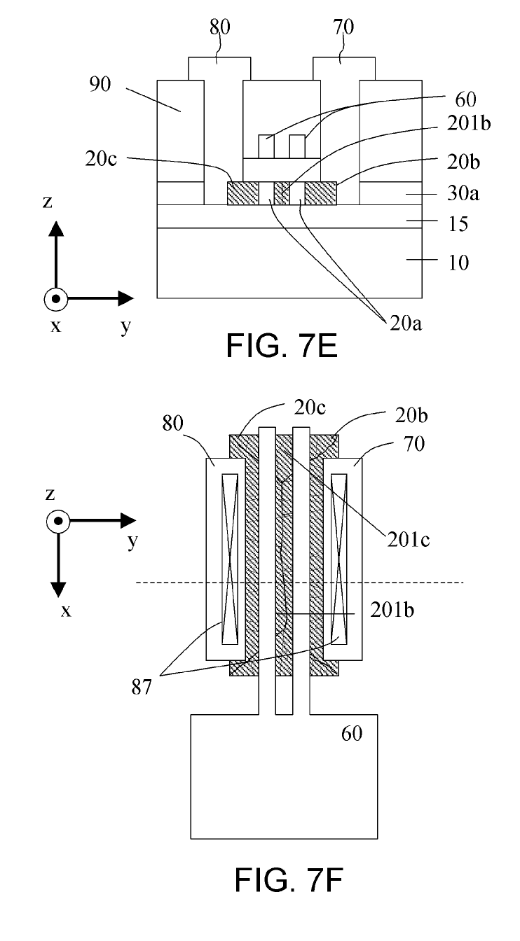

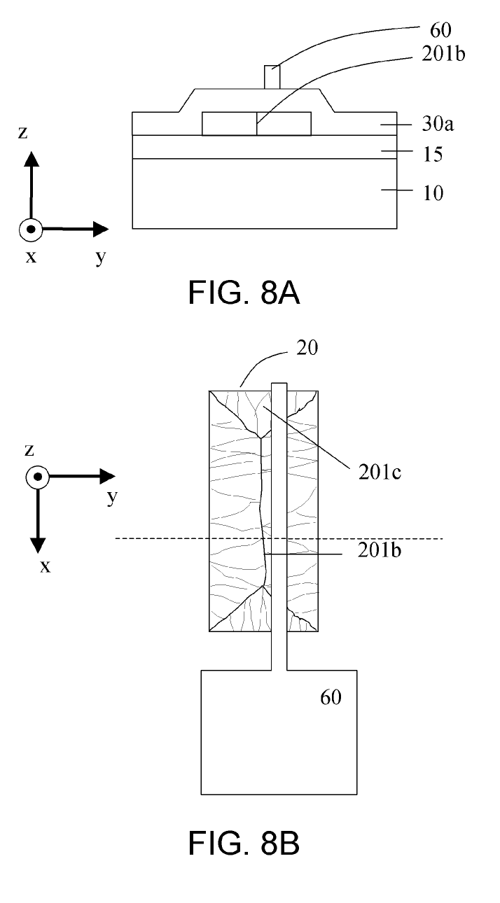

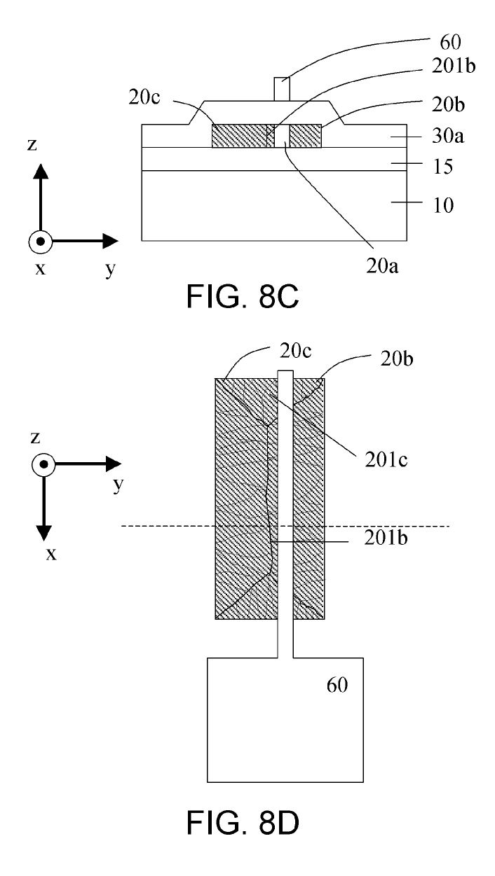

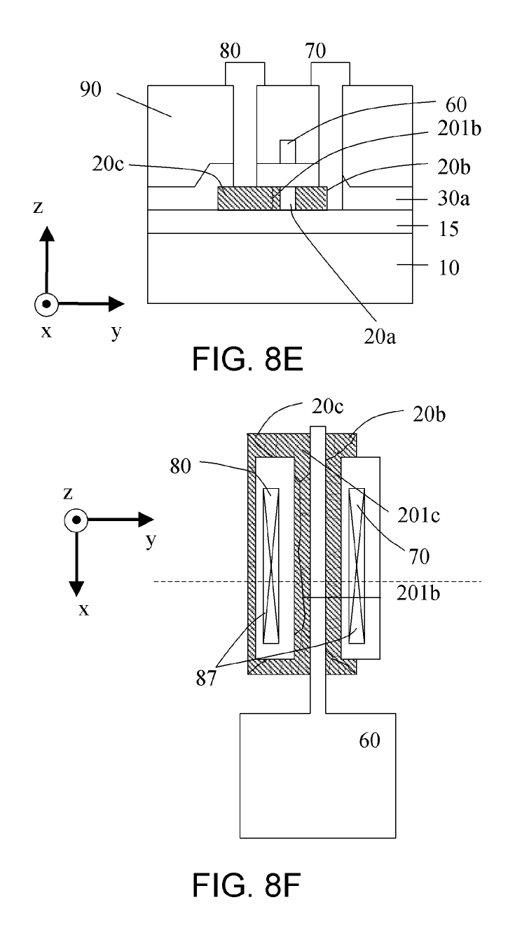

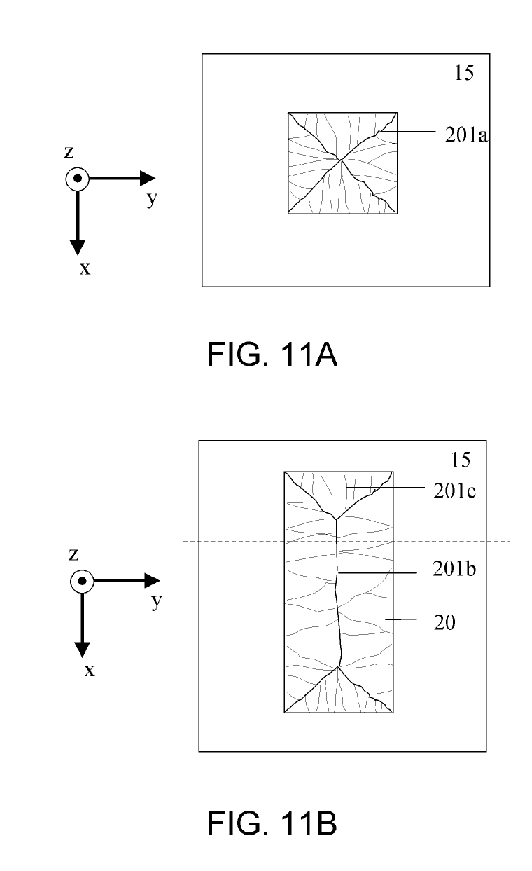

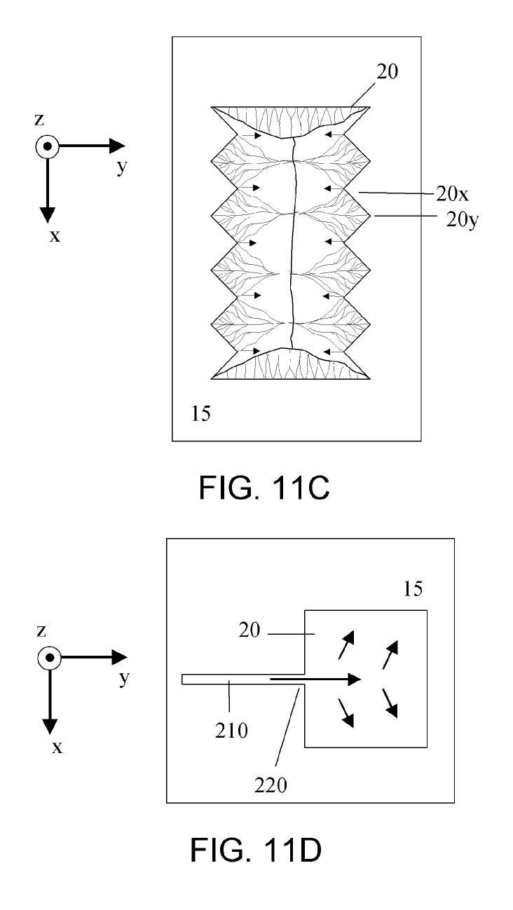

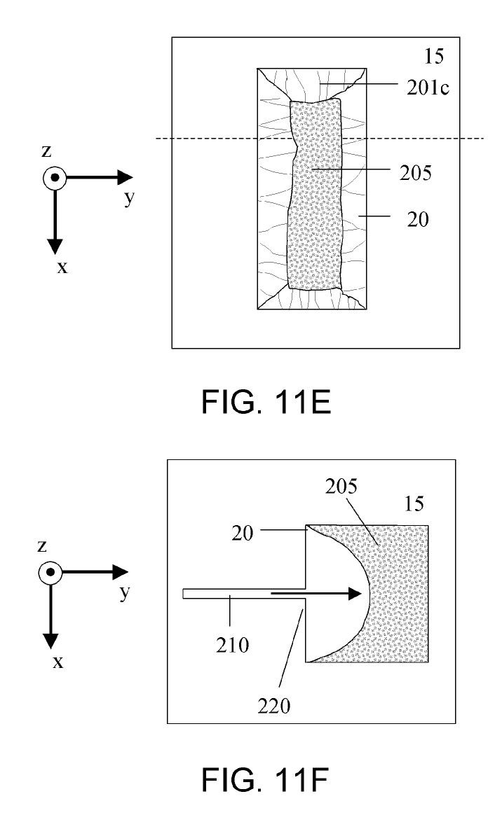

In FIGS. 11A-11F, the various shapes of the semiconductor island 20 after optical annealing, such as laser annealing, for the crystal growth are shown. If the length in the y direction of the semiconductor island 20 has about the same length in x direction (see FIG. 10A), then the crystal shape is shown in FIG. 11A. The grain boundary 201a occurs on each diagonal line to form the X-word large ground boundary (like collision). In FIG. 10B, if the length in x direction of the semiconductor island 20 is different from the length in y direction, then for example in FIG. 11B, in addition to the two longitudinal sides 201c of the semiconductor island 20, the grain boundary 201b parallel to the x-axis exists at the center line of the semiconductor island 20. When this structure is used to form the TFT, and moving direction of carriers through the channel of TFT is along the lateral growth direction, as shown in FIGS. 7B and 8B, and the channel is not set on the centerline grain boundary 201b, consequently, the probability for the carriers in perpendicularly crossing over the grain boundary is greatly reduced. Even though the grain boundary 201c, which is perpendicular to the channel direction, is still exiting, the effect in crossing the boundary 201c can be effectively reduced when the longitudinal length is larger than the transverse width in a large ratio. In this manner, the performance of TFT can be greatly improved. In the channel, only the two side regions have the gain boundary 201c, in crossing with the channel. This can further reduce the variance of performance of TFT due to the grain boundary.

If the semiconductor island 20 in FIG. 1 is a sawing shape, as shown in FIG. 10C, then the crystal grain is shown in FIG. 1C. The crystal grown in the concave region 20x is growing up in higher tendency to reach the center region of the semiconductor island 20. In this manner, the number of crystal grains can be controlled.

The shape of the semiconductor island 20 in FIG. 1 can be formed as shown in FIG. 10D, wherein the semiconductor island 20 is connected with a semiconductor peninsula 210. The temperature is down in faster speed at the peninsula 210, and the crystal growth first occurs at here and follows the crystal-growing direction indicated by arrow in FIG. 1D. As a result, single crystallization of semiconductor island 20 was realized.

In the subsequent fabrication processes, the insulating film 30a formed in the covering-film formation process, as shown in FIG. 1C, can directly serve as gate insulator of the TFT. Since temperature of the insulating film 30a is simultaneously raised when the laser annealing is performed on the semiconductor film in FIG. 1D, it can be expected to have good insulating quality in low density of the interface states and low oxide charges. If the insulating film 30a, with respect to laser, does not absorb the light, the lateral growth can only be up to 2 microns. When the semiconductor islands 20 in FIG. 10B and FIG. 10C have the y length larger than the length of later growth by factor of two, before the lateral growth reaches to the center of the island, the nucleation have occurs at the center region (see FIG. 11E) in small crystal region 205. These regions cause the poor performance of TFT.

In another point of view for FIG. 11D for the semiconductor island 20, in FIG. 11F, from the joining region 220 of the semiconductor island 20 and the semiconductor peninsula 210, the region 205 farther than the length of the lateral growth has the small grain size being occurrence. In this manner, when the larger size of semiconductor island 20 is to be crystallized, in order to prevent the small grain size in the region 205 from occurring, the length of lateral growth should be increased.

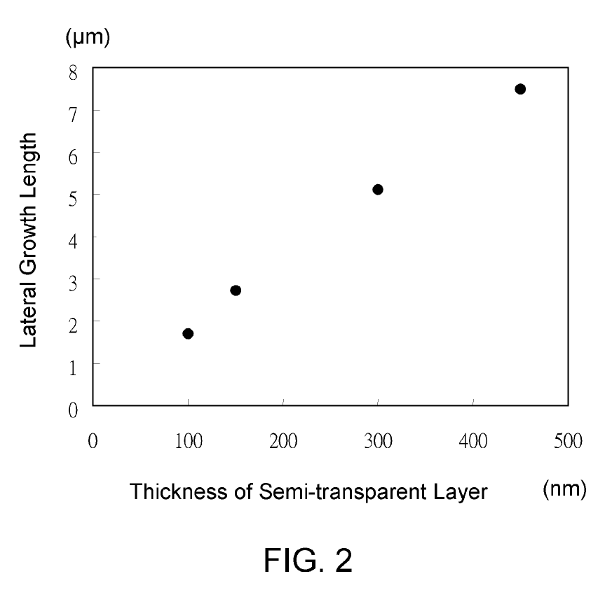

In order to increase the melting time period for the semiconductor island 20 being illuminated by the laser, as shown in FIG. 1E, the semi-transparent film 30b with absorption coefficient of 1000 40000 cm⁻¹, or preferably 4000 14000 cm⁻¹ with respect to a light beam with wavelength dependence, is disposed on the insulating film 30a. FIG. 2 shows the relation of the thickness of semi-transparent film 30b with grain size of the lateral growth, wherein the absorption coefficient is 12000 cm⁻¹. According to the lateral growth length increases when the thickness of the semi-transparent film 30b increases. It can be judged according to the drawing. If the y direction in FIGS. 11B-11C is desired to have 10 microns for the lateral grown of the semiconductor island 20, lateral growth length should be greater than 5 microns, so as to prevent the small grains in the region 205 as shown in FIG. 11F from occurring. Or, if the distance from the joining region 220 of the semiconductor island 20 and the semiconductor peninsula in FIG. 11D to any side is expected to be greater than 5 microns for this semiconductor island 20, then the lateral growth length needs to be greater than 5 microns, so as to prevent the small grains in the region 205, as shown in FIG. 11F, from occurring. Therefore, in order to have the lateral growth to have at least 5 microns, the semi-transparent film 30b should have the thickness of about greater than 300 nm.

The insulating film 30a and the semi-transparent film 30b are also annealed by the laser, so that a good insulating capability can be expected. The insulating film 30a can serve as the gate insulator for the TFT fabrication, or the insulating film 30a and the semi-transparent film 30b can serve as the gate insulator for the TFT fabrication.

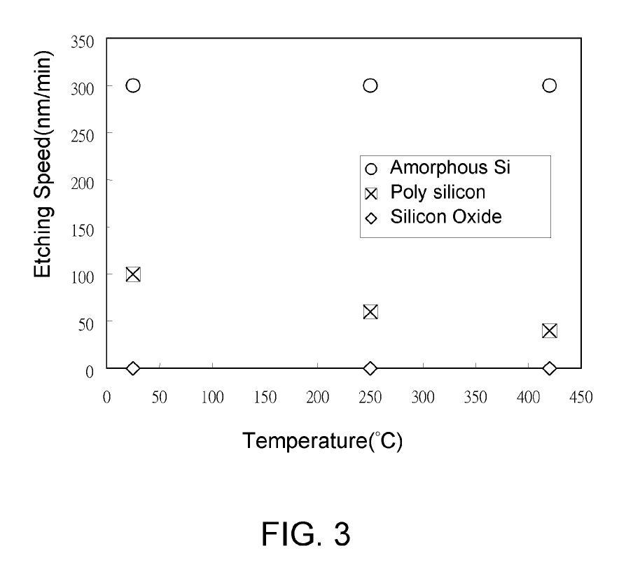

In the following descriptions, the novel etching process without using the photoresist is described. In FIG. 1B, when the semiconductor film is patterned by photolithographic and etching processes, the conventional method uses the photoresist for photolithographic process. However, when the photoresist is used in photolithographic and etching process, the surface of the semiconductor island 20 is easily contaminated or adhering particles in the air. It is difficult to assure the clean interface between the semiconductor and the gate insulator. The invention uses the difference of etching rate between the semiconductor and the oxide, or the difference of etching rate between the amorphous semiconductor and crystal semiconductor to achieve the patterning process. FIG. 3 shows the etching rated for amorphous silicon, polysilicon, and silicon oxide with respect to the hydrogen atoms. In FIG. 3, the etching rates for amorphous silicon, polysilicon, and silicon oxide are different, so that the selection etching can be achieved. This etching using the difference of etching rates between the semiconductor and the semiconductor oxide is called surface-oxide etching process, and the etching using the difference of etching rates between the amorphous semiconductor and the poly-crystal semiconductor is called phase-change etching process.

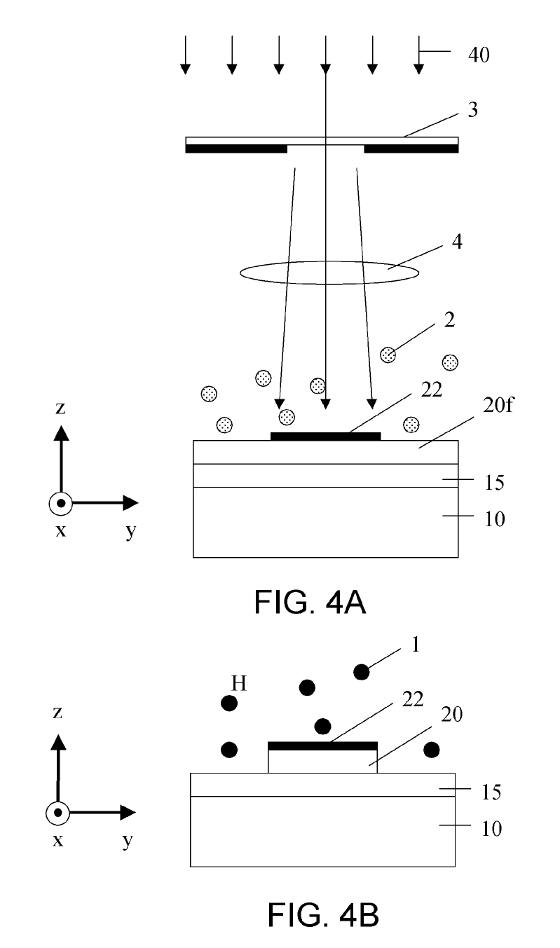

The surface-oxide etching process is described based on FIG. 4. The semiconductor film 20f on the substrate is kept in an ambience containing oxygen and is illuminated by the light beam 40 through the mask 3. Then, a quite thin semiconductor oxide film 22 is formed on the portion of the semiconductor film being illuminated by the laser. The pattern of the semiconductor oxide is the pattern from the passing light beam through the mask 3. Then, in FIG. 4B, the hydrogen atom 1 is used to etch the semiconductor film, such as silicon film. In the meantime, since the etching rate for the semiconductor film 20f is much larger than the semiconductor oxide film 22, the portion of the semiconductor film 20f without being covered by the semiconductor oxide film 22 is selectively etched. The remaining portion of the semiconductor film is covered by the oxide film and is the semiconductor island 20.

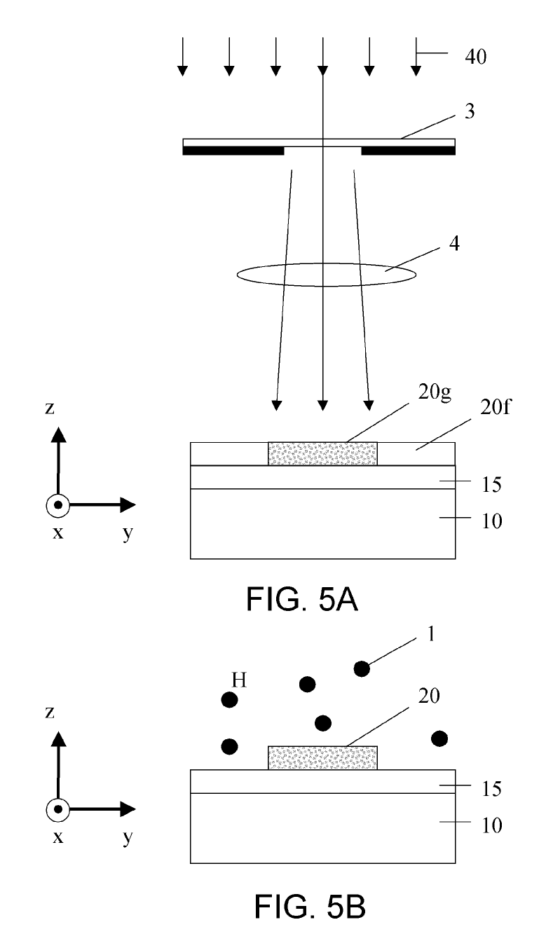

FIG. 5A is used to describe the phase-change etching process. The amorphous semiconductor film 20f on the substrate is illuminated by the light beam 40 through the mask 3. The portion of the amorphous semiconductor film 20f being illuminated by the light beam is converted into poly-crystal semiconductor 20g. The pattern being converted into poly-crystal semiconductor is the light pattern passing through the mask 3. In FIG. 5B, the hydrogen atoms 1 etch the semiconductor film. Since the etching rate for the amorphous semiconductor film is much larger than the poly-crystal semiconductor film 20g, the amorphous semiconductor film is selectively etched. The remaining portion is the poly-crystal semiconductor 20g, so that the semiconductor island 20 can be formed with a pattern matching with the passing light through the mask 3.

in the foregoing examples, the hydrogen atoms 1 are, for example, used for etching. However, hydrogen ions, or the plasma of other gases CF₄ or NF₄ can also be used for etching.

In the foregoing descriptions, although the etching process is applied to the semiconductor film, the invention is also suitable for use in metal film.

In use of above descriptions of novel method to form the semiconductor film, the formation of gate insulator, the photolithographic and etching processes, the TFT fabrication processes including the semiconductor deposition, semiconductor patterning, and the formation of the gate insulator can be performed without exposing to the air.

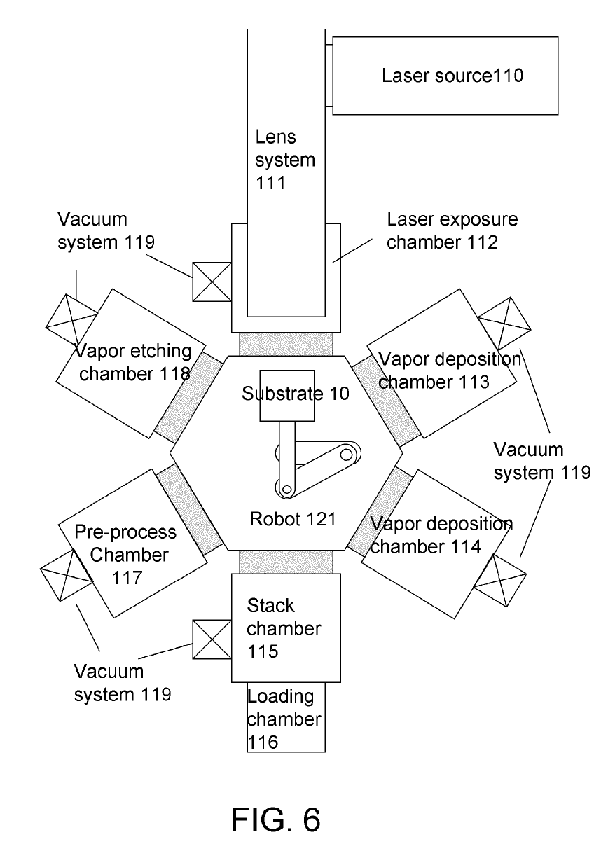

FIG. 6 is a drawing, schematically illustrating the equipment of semiconductor fabrication in multiple chambers, according to a preferred embodiment of the invention. In addition to FIG. 6, FIGS. 1A-1F are used to describe the formation of the structure on the substrate.

The glass substrate 10 is transported to the vapor deposition chamber 114 of FIG. 6 for depositing the oxide film to serve as the protection film 15. The substrate 10 is transported to the vapor deposition 113 for depositing the semiconductor film 20f. Then, the substrate 10 is transported to the light beam exposure chamber 112, and the light beam 40 passing through the mask 3 illuminates the semiconductor film 20f for the surface-oxide as described in FIG. 4A or the phase-change for crystallizing the semiconductor film as described in FIG. 5A. Then, the substrate 10 is transported to the vapor etching chamber 118 to etch the portion of the semiconductor film 20f not being covered by the surface oxide or not converted into the phase of poly-crystal. As a result, the semiconductor island 20 remains as shown in FIG. 1B. The surface shape of the semiconductor island 20 can be any one in FIGS. 10A-10D. Then, the substrate 10 is transported to the vapor deposition chamber 114, as shown in FIG. 1C, and the insulating film 30a and the semi-transparent film 30b are deposited. The substrate 10 is again transported to the light beam exposure chamber 112, as shown in FIG. 1D and FIG. 1F, the light beam 40 is used to crystallize the semiconductor island. In the foregoing processes, it is not necessary to be exposed to the air. Since the insulating film 30a can be directly used as the gate insulator, the interface between the semiconductor island 20 and the gate insulator 30a can be assured to be good quality, so that high uniformity and high performance of TFT can be achieved.

In addition, the metal deposition chamber can be used to deposit the metal film or semiconductor film in low resistance to serve as the gate film. Then, using the patterning process as described in FIGS. 4A-4B and 5A-5B, the shape of gate electrode can be patterned. Or, the light beam exposure chamber 112 can also be used as the vapor etching chamber.

Embodiment 1

FIGS. 1A-1F are used to describe a first embodiment of the invention. In FIG. 1A, the silicon oxide or silicon nitride film is deposited on the substrate 10 to serve as the protection film 15. The protection film can use the PECVD(plasma enhanced chemical vapor deposition) using tetra ethoxy silane (TEOS) with oxygen and nitrogen as the raw materials, under a temperature of, for example, 300° C., so as to deposit a thickness of 300 nm. However, SiH with oxygen or nitrogen can be also used for raw materials for PECVD. An amorphous silicon film with a thickness of 50 nm to serve as the semiconductor film 20f is deposited on the protection film 15. The deposition process was PECVD using SiH₄ as the raw material under a temperature of, for example, 500° C. In FIG. 1B, the amorphous silicon film is patterned to form the semiconductor island 20. The surface of the semiconductor island 20 has the shape as shown in FIGS. 10A-10D. The semiconductor island 20 has a size of 0.2 μm×0.4 μm up to 15 μm×30 μm. In FIG. 1C, a silicon oxide film with thickness of 100 nm is formed on over the semiconductor island 20, to serve as the insulating film 30a. The deposition process of silicon oxide film can be, for example, PECVD method using TEOS and oxygen as the raw material under a temperature of, for example, 300° C. In FIG. 1E, an silicon oxynitride film with thickness of 100 nm 1200 nm is deposited to serve as the semi-transparent film 30b, wherein the absorption coefficient with respect to light beam 40 is about 2000-20000 cm⁻¹, and preferably 4000-12000 cm⁻¹. The silicon oxynitride film is deposited by PECVD using SiH₄, O, and N as the raw material under a temperature of, for example, 300° C.

In FIG. 1D, the light beam 40 illuminates over the substrate 10 to cause the semiconductor island 20 to be crystallized. For the size of the semiconductor island 20 in y direction in FIG. 10A-C is less than 4 microns, the crystallized grains have the shape as shown in FIGS. 11A-11C. Or in FIG. 10D, for the distance from the joining region 220 of the semiconductor island 20 and the semiconductor peninsula in FIG. 10D to any side is less than 2 microns for this semiconductor island 20, the crystal is about a single crystal without obvious grain boundary as shown in FIGS. 11D. When the size of the semiconductor island 20 is greater above dimensions, then small gains at region 205, as shown in FIGS. 11E-11F, occurs due to insufficient lateral growth length. Under this consideration, after the step in FIG. 1C such as FIG. 1E, a silicon oxynitride with thickness of 10 nm 1200 nm to serve as the semi-transparent film 30b is formed, wherein it has the absorption coefficient of 2000-20000 cm⁻¹, and preferably 4000-12000 cm⁻¹ with respect to light beam 40. The silicon oxynitride film is deposited by using SiH₄, O, and N as the material with the PECVD. In FIG. 1F, the light beam 40 illuminates the silicon film. For the semiconductor island in FIGS. 10A-C, even if the semiconductor island in y direction is greater than 4 microns, the grain shapes in FIGS. 11A-11C can be obtained without difficulty. For the semiconductor in FIG. 10D, even if the distance from the joining region 220 of the semiconductor island 20 and the semiconductor peninsula to any side is greater than 2 microns, the grain shapes in FIGS. 11D can be obtained without difficulty.

Now, the subsequent processes for forming the TFT are performed. The semiconductor island 20, as shown in FIGS. 11B-11D, directly serves as the active area of the TFT. When the surface of the silicon island 20 has only the insulating film 30a without the semi-transparent film 30b, the insulating film 30a is directly used as the gate insulator. When the surface has also the semi-transparent film 30b, as shown in FIG. 1F, then the semi-transparent film 30b is removed by etching, as shown in FIG. 1D, and the insulating film 30a are used as the gate insulator.

In FIGS. 7-9, the subsequent processes for TFT are described. The sputtering deposition is used with, for example, metal such as Ta to from the metal film over the gate insulator 30a in FIG. 1D. The metal film is patterned to form the electrode 60. The different shapes of the semiconductor island as the gate electrode can be determined according to the drawings 11B-11D.

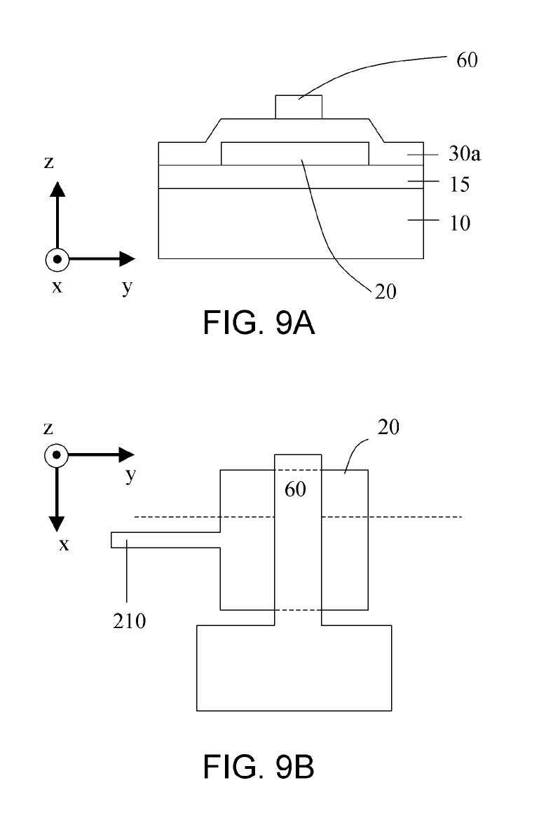

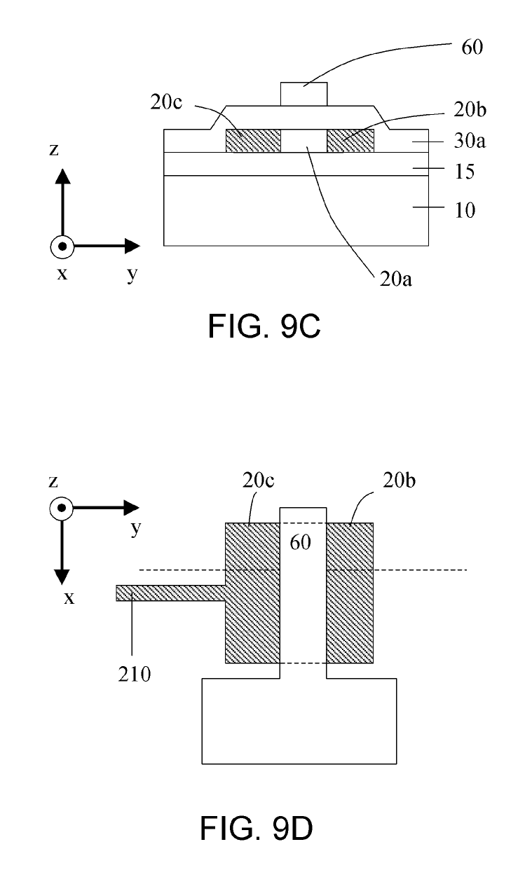

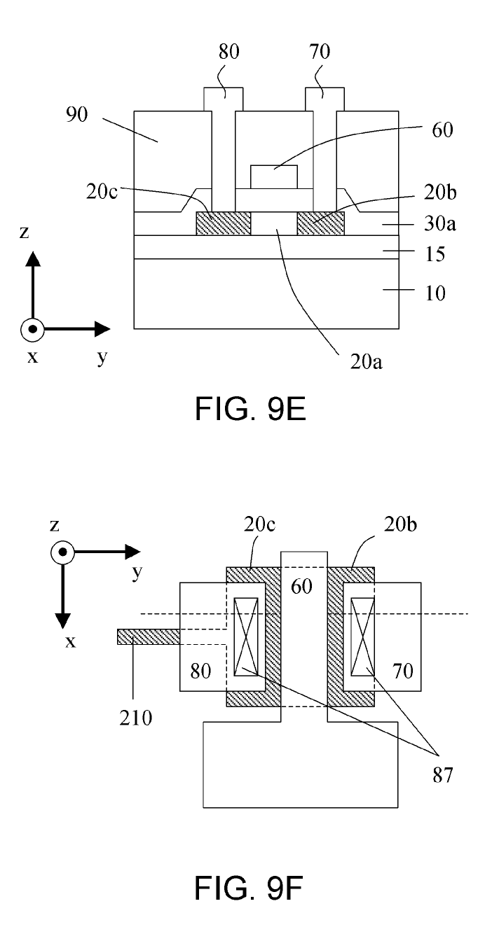

Th shape of semiconductor island is in FIG. 11B-11C are described first. The gate shape can be dual gate structure as shown in FIG. 7A and FIG. 7B or the single gate as shown in FIG. 8A and FIG. 8B. In these two shapes, the gate electrode is not on the central gain boundary 201b. When the shape of the semiconductor island 20 is shown in FIG. 11D, then since the semiconductor island 20 is a single crystal, the gate shape for the single gate or the multi-gate can be formed. FIGS. 9A-9B are the example of single gate. The embodiment with single gate is shown in FIG. 9A and FIG. 9B.

In the following, FIGS. 7C-7D or FIGS. 8C-8D, or FIGS. 9C-9D are described. Taking the gate electrode 60 as the mask, the donors or the acceptors in ions are implanted into the source region 20b, drain region 20c of the semiconductor island, and the adjacent region to the grain boundary 201b in FIGS. 7C-7D.

As shown in FIGS. 7E-7F, FIGS. 8E-8F, or FIGS. 9E-9F, the silicon oxide film is deposited to serve as the interlayer insulating film 90. The deposition process can be PECVD with materials of TEOS and oxygen and nitride. The laser annealing, the furnace annealing, or the rapid thermal annealing can be performed to activate the implanted dopants. Then, the inter-layer insulating film above the source region and the drain region is patterned by photolithographic and etching processes to form a contact hole 87. After the source electrode 70 and the drain electrode 80 are formed, the TFT is accomplished.

According to the fabrication processes for TFT in the invention, since there is no the grain boundary perpendicularly crossing over the moving direction of the carriers at the channel under the gate electrode, and the gate insulator is annealed by laser, the TFT of the invention can achieve high performance. In the embodiment, the shape of semiconductor island in FIG. 10B and FIG. 10C can have the good device property with electron mobility by 360 cm ²/V-s. The shape of semiconductor island in FIG. 10D can have the good device property with electron mobility by 460 cm²/V-s.

Embodiment 2

The embodiment of the invention has described the novel technology of photolithographic and etching process without using the photoresist and without exposing into the air, as shown in FIG. 1 and FIG. 6. FIGS. 1A-1F describe the fabrication processes for the TFT. FIG. 6 is the equipment in several processes chamber to perform the processes. For the equipment in FIG. 6, it includes the vapor deposition chamber 113, 114 for deposition, the light beam exposure chamber 112 for illuminate the light beam over the substrate, the vapor etching chamber 118, the loading chamber 116, the robot arm 121, and the vacuum system 119. In addition, the pre-process chamber 117 is used to clean the substrate.

The substrate 10 is loaded in the loading chamber 116, and then transported to the pre-process chamber 117 through the stack chamber 115 for cleaning. Then, the substrate 10 is shifted to the vapor deposition chamber 114 to perform PECVD with TEOS, so as to form the protection film 15 over the substrate 10 in FIG. 1A. The substrate 10 is shifted to the vapor deposition chamber 113 for performing PECVD with SiH₄ to form the amorphous silicon film as the semiconductor film 20f. After depositing the semiconductor film, the surface is at a state terminated by the hydrogen atoms for lasting few hours without being oxidized. The substrate 10 is then shifted to the light beam exposure chamber 112.

As described in FIGS. 4A-4B, the chamber 112 is in the oxygen ambience, and the amorphous silicon film 20f is illuminated by the light beam 40 through the mask 3. After the silicon surface being originally terminated with the hydrogen atoms is illuminated by the laser, the hydrogen atoms departs and the surface in the oxygen ambience forms a quite thin silicon oxide film 22. The pattern of silicon oxide on the surface is from the light beam capable of passing the mask 3. The intensity of light beam is about 0.01-800 mJ/cm², and preferably 0.1-200 mJ/cm². It has already been sufficient to perform once. Then, the substrate 10 is shifted to the vapor etching chamber 118. In the vapor etching chamber 118, the tungsten filament (not shown) is used to raise the temperature up to 1500° C.-2500° C. The hydrogen gas is flushed over the tungsten filament to de-couple the hydrogen gas into hydrogen atoms. In FIG. 4B, when the substrate 10 is under hydrogen ambience, since the etching rate for the silicon film 20f is much larger than the silicon oxide 22, the portion of the silicon film 20f without being covered with oxide is selectively etched. As a result, the pattern of the mask forms the pattern of the semiconductor island 20, such as silicon island 20, as shown in FIG. 1B. The shape of the silicon island 20 can be, for example, any one in FIGS. 10A 10D. Then, the substrate 10 is shifted to the vapor deposition chamber 114, as shown in FIG. 1C, for depositing the silicon oxide film with thickness of 100 nm over the semiconductor island 20 to serve as the insulating film 30a. The deposition uses mainly TEOS and oxygen and nitrogen as the material in PECVD. After then, SiH₄ and oxygen and nitrogen as the materials in the same chamber 114 to perform PECVD to form the silicon oxynitride film as the semi-transparent film 30b by the thickness of 100 1200 nm and absorption coefficient of 2000-20000 cm⁻¹ and preferably 4000-12000 cm⁻¹ with respect to the illuminating light beam 40.

The substrate 10 is then shifted to light beam exposure chamber 112 in FIG. 6 for illuminating the light beam 40 on the semiconductor island 20 as shown in FIG. 1D or FIG. 1F. As a result, the crystal grains shown in FIGS. 11A-11D are obtained.

The process now is shifted to the TFT fabrication processes. If the surface of the silicon island 20 only has the insulating layer 30a but no the semi-transparent film 30b, then the insulating film 30a can remain to directly serve as the fate insulator. If the semi-transparent film 30b is also included, the semi-transparent film 30b is removed by etching to have the insulating film in FIG. 1D as the gate insulator.

The TFT is continuously fabricated by the subsequent processes, as described in embodiment 1. In this embodiment 2, during the fabrication processes for TFT in FIG. 1A-1F, the deposition protection film 15, the formation of semiconductor film 20f, the patterning process for the semiconductor island 20, formation of the gate insulator 30a and the semi-transparent film 30b, laser annealing on the semiconductor island 20 and the gate insulator 30a are at least performed in series without being exposed under the air. As a result, the improvement of device performance, uniformity of device property, and improvement of yield are having significant effect. According to the invention, the N-type TFT can have good properties of the electron mobility by 560 cm²/V-s, the subthreshold swing of 0.2 V/dec, threshold voltage Vth of 0.1V. Also and, the threshold voltage of TFT has the distribution within 50 mV.

Embodiment 3

FIGS. 1A-1F and FIG. 6 are used to described the embodiment. FIGS. 1A-1F describe the fabrication processes for TFT, the equipment as described in FIG. 6 is used for actual fabrication machines.

The substrate 10 is loaded in the loading chamber 116, and then transported to the pre-process chamber 117 through the stack chamber 115 for cleaning. Then, the substrate 10 is shifted to the vapor deposition chamber 114 to perform PECVD with TEOS, so as to form the protection film 15 over the substrate 10 in FIG. 1A. The substrate 10 is shifted to the vapor deposition chamber 113 for performing PECVD with SiH₄ to form the amorphous silicon film as the semiconductor film 20f in FIG. 1A.

Then, the substrate 10 is then shifted to the light beam exposure chamber 112. As described in FIGS. 5B, the amorphous silicon film 20f is illuminated by the light beam 40 through the mask 3 to convert into the polysilicon film 20g. The pattern being converted into polysilicon matches to the pattern of the mask 3 for the portion allowing light beam to pass. The intensity of laser is about 20-800 mJ/cm², and preferably 100-400 mJ/cm². It has been sufficient for performing once. Then, the substrate 100 is shifted to the vapor etching chamber 118. In the vapor etching chamber 118, the tungsten filament (not shown) is used to raise the temperature up to 1500° C.-2500° C. The hydrogen gas is flushed over the tungsten filament to de-couple the hydrogen gas into hydrogen atoms. In FIG. 5B, the hydrogen atoms are used to etch the silicon film. Since the etching rate on the amorphous silicon at region 20f is larger than the polysilicon at region 20g, the amorphous silicon at the region 20f is selectively etched and the polysilicon at region 20g remains. As a result, the pattern for the mask allowing the light beam to pass determines the pattern of silicon island 20. Up this step, the structure is shown in FIG. 1B.

The shape of silicon island 20 can be any one in FIG. 10A-10D. Then, the substrate 10 is shifted to vapor deposition chamber 114. As shown in FIG. 1C, a silicon oxide film is deposited on the semiconductor island 20 with thickness of 100 nm to serve as the insulating film 30a. The deposition uses mainly TEOS and oxygen and nitrogen as the material in PECVD. Then, another PECVD with SiH₄, oxygen, and nitrogen is performed at the same chamber 114 to form a silicon oxynitride film to serve as the semi-transparent film 30b, with thickness of 100 1200 nm and absorption coefficient of 2000-20000 cm⁻¹, and preferably 4000-12000 cm⁻¹with respect to light beam 40.

The substrate 10 is shifted to the light beam exposure chamber 112 in FIG. 6, and then for illuminating the light beam 40 on the semiconductor island 20 as shown in FIG. 1D or FIG. 1F. As a result, the crystal grains shown in FIGS. 11A-11D are obtained.

The process now is shifted to the TFT fabrication processes. If the surface of the silicon island 20 only has the insulating layer 30a but no the semi-transparent film 30b, then the insulating film 30a can remain to directly serve as the fate insulator. If the semi-transparent film 30b is also included, the semi-transparent film 30b is removed by etching to have the insulating film in FIG. 1D as the gate insulator.

The TFT is continuously fabricated by the subsequent processes, as described in embodiment 1. In this embodiment 3, during the fabrication processes for TFT in FIG. 1A-1F, the deposition protection film 15, the formation of semiconductor film 20f, the patterning process for the semiconductor island 20, formation of the gate insulator 30a and the semi-transparent film 30b, laser annealing on the semiconductor island 20 and the gate insulator 30a are at least performed in series without being exposed under the air. As a result, the improvement of device performance, uniformity of device property, and improvement of yield are having significant effect. According to the invention, the N-type TFT can have good properties of the electron mobility by 560 cm²/V-s, the subthreshold swing of 0.2 V/dec, threshold voltage Vth of 0.1V. Also and, the threshold voltage of TFT has the distribution within 50 mV.

In the foregoing descriptions, although the TFT structure has no the light-doped drain (LDD) structure, the LDD or the GOLD can also be suitable for use in the embodiments.

In the foregoing descriptions, a preferred range of the absorption coefficient for the semi-transparent layer is shown as the example. The absorption coefficient may actually vary with the wavelength of the excimer laser being used. However, the inventive aspect remains the same for the different wavelengths of light beam, such as 248 nm, 308 nm, or 351 nm, which do not cause effective difference in results.

In addition, the invention is not limited to TFT. Under the same principle of the invention, it allows various changes. For example, the material or the materials, or the deposition method can be properly changed according to the actual application and designs.

The invention provides the method for fabricating TFT. It is not necessary to include the photoresist used in conventional photolithographic and etching processes. Also and, the photolithographic and etching processes are not necessary to be exposing under the air. By a simple process, the silicon island by lateral growth or single-crystal silicon island can be achieved. The property of gate insulator can be improved. As a result, the fabrication process for TFT can significantly improve the TFT performance, the yield, and the throughput.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

1. A method for fabricating a transistor, comprising:
forming a semiconductor film over a substrate;
forming a semiconductor island by patterning the semiconductor film;
forming an insulating film over the substrate;
performing an optical annealing process to crystallize the semiconductor island; and
forming a transistor on the semiconductor island.

2. The method of claim 1, wherein a portion of the insulating film serves as a gate insulator of the transistor.

3. The method of claim 1, after the step of forming the insulating film comprising:
forming a semi-transparent film on the insulating film, wherein the semi-transparent film has an absorption coefficient of 4000 cm⁻¹-20000 cm⁻¹ with respect to a light beam.

4. The method of claim 1, wherein the step of forming the insulating film comprises:
forming a silicon oxide film; and
forming a semi-transparent film on the silicon oxide film, wherein the semi-transparent film has an absorption coefficient of 4000 cm⁻¹-20000 cm⁻¹.

5. The method of claim 1, wherein the step of forming the semiconductor island comprises:
forming an amorphous semiconductor film over the substrate;
illuminating the amorphous semiconductor film by a light beam through a mask, to convent a portion of the amorphous semiconductor film being illuminated into a crystallized semiconductor; and
performing a gas etching process, to remove a portion of the amorphous semiconductor without being crystallized.

6. The method of claim 1, wherein the step of forming the semiconductor island comprises:
forming an amorphous semiconductor film over the substrate;
performing an light exposure process, wherein the amorphous semiconductor film is in an oxygen ambience and is illuminated by a light beam through a mask, so as to form an oxide film on the amorphous semiconductor film at a portion being exposed to the light beam; and
performing a gas etching process, to remove a portion of the amorphous semiconductor film not being covered by the oxide film.

7. The method of claim 6, wherein the step of performing the gas etching process comprises:
producing hydrogen atoms; and
etching the amorphous semiconductor film by the hydrogen atoms.

8. The method of claim 1, wherein at least the steps of from the step of forming the semiconductor film to the step of forming the insulating film are performed in chambers without being exposed to the air.

9. An equipment for fabricating a transistor, comprising at least one operation chamber in a close space for at least performing the steps of from the step of forming the semiconductor film to the step of forming the insulating film the steps in the method of claim 1, without being exposed to the air.

10. A patterning method on an amorphous semiconductor film, comprising:
preparing a mask with a pattern, allowing a light to pass;
illuminating a light beam through the mask onto the amorphous semiconductor film, so as to crystallize a portion of the amorphous semiconductor film into a crystal semiconductor portion; and
performing a gas etching process, to remove another portion of the amorphous semiconductor film other than the crystal semiconductor portion.

11. The method of claim 10, wherein the amorphous semiconductor film comprises amorphous silicon film or amorphous germanium film.

12. The method of claim 10, wherein the gas etching process uses hydrogen atoms for etching.

13. A patterning method on an amorphous semiconductor film, comprising:
preparing a mask with a pattern, allowing a light to pass;
disposing the amorphous semiconductor film in an oxygen ambience;
illuminating a light beam through the mask onto the amorphous semiconductor film, so as to form an oxide film on a portion of the amorphous semiconductor film; and
performing a gas etching process, to remove another portion of the amorphous semiconductor film not being covered by the oxide film.

14. The method of claim 13, wherein the amorphous semiconductor film comprises amorphous silicon film or amorphous germanium film.

15. The method of claim 13, wherein the gas etching process uses hydrogen atoms for etching.

16. A structure of thin-film transistor (TFT), comprising:
a poly-crystal semiconductor island, formed on a substrate, wherein the poly-crystal semiconductor island is with respect to a rectangular region having a long side and a short side, wherein a plurality long-shape crystal grains from a center strip region along the direction of the long side to the long side;
a gate insulating film, over the semiconductor island; and
a strip gate, located on the gate insulating film between the center grain boundary and the long side, wherein a direction of the strip gate in along the direction of the long side; and
a source region and a drain region are parts of the semiconductor island at each side of the strip gate.

17. The structure of claim 16, wherein the number of the long crystal grains is determined by a ratio of the long side to the short side.

18. The structure of claim 16, wherein the semiconductor island has a saw-like periphery along the long sides.

19. The structure of claim 16, further comprising a strip semiconductor peninsula joining to one side of the semiconductor island.

20. The structure of claim 16, wherein the center strip region is a center grain boundary.

21. The structure of claim 16, wherein the semiconductor island is used as an active island of the thin-film transistor without additional patterning.
